(19) United States
(12) Patent Application Publication
(10) Pub. No.: US 2024/0295022 A1
(43) Pub. Date: Sep. 5, 2024

(54) PROCESSING METHOD AND PROCESSING APPARATUS

(71) Applicant: Tokyo Electron Limited, Tokyo (JP)

(72) Inventor: Hiroki MURAKAMI, Yamanashi (JP)

(21) Appl. No.: 18/581,976

(22) Filed: Feb. 20, 2024

(30) Foreign Application Priority Data
Mar. 3, 2023 (JP) 2023-032588

(51) Int. Cl. C23C 16/44; C23C 16/40; H01L 21/02

(52) U.S. Cl. CPC C23C 16/4405; C23C 16/403; C23C 16/4404; H01L 21/02178; H01L 21/02181; H01L 21/02186

(57) ABSTRACT

A processing method includes supplying a halogen-containing gas into a process chamber and removing a metal oxide film in the process chamber.

### CROSS-REFERENCE TO RELATED APPLICATIONS

This application is based upon and claims priority to Japanese Patent Application No. 2023-032588, filed on Mar. 3, 2023, the entire contents of which are incorporated herein by reference.

### BACKGROUND

### 1. Field of the Invention

The present disclosure relates to processing methods and processing apparatuses.

### 2. Description of the Related Art

A technique of removing, through washing, a metal oxide film attached to the surface of a washing target by using a cleaning solution is known (see, for example, Japanese Patent Publication No. 2005-167087).

### SUMMARY

According to an aspect of the present disclosure, a processing method includes supplying a halogen-containing gas into a process chamber and removing a metal oxide film in the process chamber.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a flowchart illustrating a processing method according to an embodiment;

FIG. 2 is a flowchart illustrating an example of a film removal step;

FIG. 3 is a longitudinal cross-sectional view illustrating a processing apparatus according to an embodiment;

FIG. 4 is a transversal cross-sectional view illustrating the processing apparatus according to the embodiment; and

FIG. 5 is a graph illustrating a relationship between an etching pressure and an etching amount of an AlO film.

### DETAILED DESCRIPTION

The present disclosure provides a technique of removing a metal oxide film through a dry process.

Hereinafter, non-limiting embodiments of the present disclosure will be described with reference to the drawings. Throughout all of the appended drawings, the same or corresponding members or components are designated by the same or corresponding reference symbols, and duplicate description thereof will be omitted.

### [Processing Method]

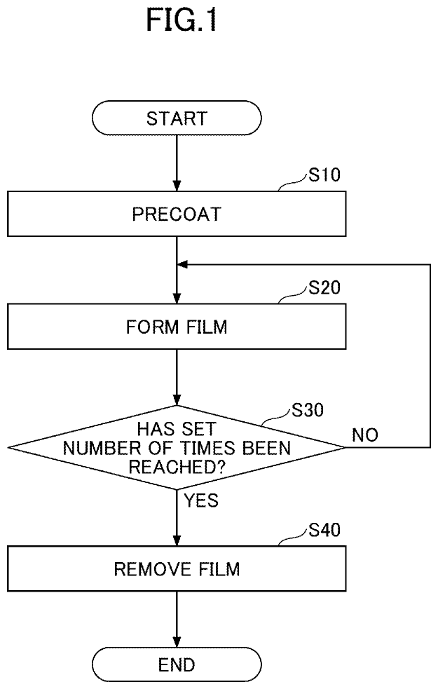

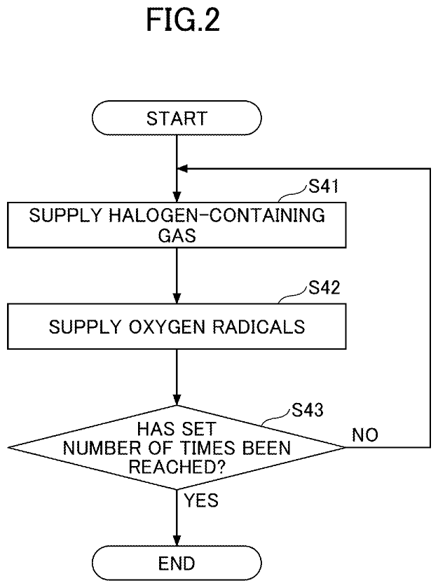

A processing method according to the embodiment will be described with reference to FIGS. 1 and 2. FIG. 1 is a flowchart illustrating the processing method according to the embodiment. FIG. 2 is a flowchart illustrating an example of film removal step S40.

As illustrated in FIG. 1, the processing method according to the embodiment includes precoat step S10, film formation step S20, determination step S30, and film removal step S40. Precoat step S10, film formation step S20, and film removal step S40 are performed in the same process chamber.

Precoat step S10 includes coating the interior of a process chamber with a precoat film. Precoat step S10 is performed, for example, before a metal oxide film is formed in the interior of the process chamber. The precoat film has etching resistance to a halogen-containing gas higher than in a material that forms the process chamber. Amorphous silicon (a-Si), silicon nitride (SiN), silicon carbonitride (SiCN), titanium nitride (TiN), or tungsten is suitable as a material forming the precoat film. An object to be coated with the precoat film (hereinafter may be referred to as a “coating target”) includes at least a member etched by a halogen-containing gas supplied into the process chamber in film removal step S40, such as a member formed of quartz. For example, when a process chamber formed of quartz is used, the coating target includes the inner wall of the process chamber. For example, when a part formed of quartz is used in the interior of the process chamber, the coating target includes the part formed of quartz.

By performing precoat step S10, the surface of the member formed of quartz is coated with the precoat film. Thus, etching of the member formed of quartz can be prevented in film removal step S40. As a result, the lifetime of the part formed of quartz can be extended. In the case in which the interior of the process chamber does not include the member etched by the halogen-containing gas, or in which the interior of the process chamber is already coated with a precoat film, precoat step S10 may be omitted.

Film formation step S20 is performed after precoat step S10. Film formation step S20 includes housing a substrate in the interior of the process chamber and forming a metal oxide film on the substrate. In film formation step S20, the metal oxide film is not only formed on the surface of the substrate but also deposited in the interior of the process chamber. The metal oxide film may be a high-κ film such as an aluminum oxide (AlO) film, a titanium oxide (TiO) film, or a hafnium oxide (HfO) film.

Determination step S30 is performed after film formation step S20. In determination step S30, it is determined whether or not film formation step S20 has been performed a set number of times. If the set number of times has not been reached (“NO” in determination step S30), film formation step S20 is performed again. If the set number of times has been reached (“YES” in determination step S30), film removal step S40 is performed. Thus, film formation step S20 is repeatedly performed until the set number of times has been reached. The set number of times may be one or more. For example, the set number of times may be determined in accordance with the thickness of the metal oxide film deposited in the interior of the process chamber in film formation step S20.

Film removal step S40 is performed after determination step S30. As illustrated in FIG. 2, film removal step S40 includes halogen-containing gas supply step S41, oxygen radical supply step S42, and determination step S43.

Halogen-containing gas supply step S41 includes supplying the halogen-containing gas into the process chamber and removing the metal oxide film in the process chamber. The metal oxide film includes the metal oxide film deposited in the interior of the process chamber in film formation step S20. The halogen-containing gas may be a hydrogen halide gas. Examples of the hydrogen halide gas include hydrogen fluoride (HF) gas, hydrogen chloride (HCl) gas, hydrogen bromide (HBr) gas, and hydrogen iodide (HI) gas. The halogen-containing gas may be a halogen gas. Examples of the halogen gas include fluorine (F₂) gas, chlorine (Cl₂) gas, bromine (Br₂) gas, and iodine (I₂) gas. The halogen-containing gas may be a gas mixture of a hydrogen halide gas and a halogen gas.

The metal oxide film is readily etched through wet etching using dilute hydrofluoric acid (DHF). Meanwhile, in dry etching using a halogen-containing gas, especially fluorine-containing gas which is highly reactive, the halogen-containing gas reacts with the metal oxide film to form a metal fluoride. Because the metal fluoride has a very high melting point, the metal fluoride is not readily removed through etching.

Therefore, in halogen-containing gas supply step S41, the metal oxide film in the interior of the process chamber is removed by forming an environment in which wet (liquid phase)-like reaction using the halogen-containing gas occurs in the interior of the process chamber. Specifically, by maintaining the interior of the process chamber at a temperature of from room temperature through 40 degree Celsius (° C.) and maintaining the interior of the process chamber at a high pressure, it is possible to form the environment in which wet-like reaction occurs. The room temperature may be a temperature of 10° C. or higher and 30° C. or lower and is, for example, 23° C. For example, in the case in which the metal oxide film is an AlO film and the halogen-containing gas is hydrogen fluoride gas, by maintaining the interior of the process chamber at a temperature of from room temperature through 40° C. and maintaining the interior of the process chamber at a high pressure, i.e., at a pressure of 100 Torr (13.3 kilopascals (kPa)) or higher, it is possible to form the environment in which wet-like reaction occurs.

In halogen-containing gas supply step S41, removal of the metal oxide film is not performed through complete wet etching reaction, and thus, metal halides can be formed. Especially, if halogen-containing gas supply step S41 is continuously performed, halogenation of the metal oxide film proceeds from the surface thereof to a deeper position, and etching of the metal oxide film cannot sufficiently proceed. Therefore, it is preferable that every time halogen-containing gas supply step S41 is continuously performed for a predetermined time, oxygen radical supply step S42 described below be performed to remove the metal halide.

Oxygen radical supply step S42 includes supplying oxygen radicals into the process chamber. The metal halides (e.g., AlF) formed in halogen-containing gas supply step S41 are discharged from the interior of the process chamber in the form of gas of, for example, metal oxides (e.g., AlO) or a halogen (e.g., F) by the action of the oxygen radicals. Thus, the metal halides formed in halogen-containing gas supply step S41 are removed. The oxygen radicals are obtained, for example, by supplying an oxygen-containing gas into the process chamber and forming a plasma from the oxygen-containing gas. The oxygen-containing gas may be oxygen (O₂) gas, ozone (O₃) gas, water vapor (H₂O), or any combination thereof. Hydrogen (H₂) gas may be added to the oxygen-containing gas. In the cases, for example, in which the etching rate of the metal oxide film does not decrease, oxygen radical supply step S42 may be omitted.

Determination step S43 is performed after oxygen radical supply step S42. In determination step S43, it is determined whether or not halogen-containing gas supply step S41 and oxygen radical supply step S42 have been performed a set number of times. If the set number of times has not been reached (“NO” in determination step S43), halogen-containing gas supply step S41 and oxygen radical supply step S42 are performed again. If the set number of times has been reached (“YES” in determination step S43), film removal step S40 is ended. Thus, halogen-containing gas supply step S41 and oxygen radical supply step S42 are alternately repeated until the set number of times is reached. In this case, the metal oxide film can be continuously etched, involving approximately no reduction in the etching rate. The set number of times may be one or more. For example, the set number of times may be determined in accordance with the thickness of the metal oxide film deposited in the interior of the process chamber immediately before the start of film removal step S40.

As described above, according to the processing method according to the embodiment, the halogen-containing gas is supplied into the process chamber to remove the metal oxide film in the interior of the process chamber. In this case, the metal oxide film can be removed through a dry process. This can shorten the downtime of the processing apparatus that will follow the removal of the metal oxide film in the process chamber. As a result, the operation efficiency of the processing apparatus is increased.

Meanwhile, when the metal oxide film in the process chamber is removed through wet etching using a cleaning solution, for example, the interior of the process chamber is released to open air, and the parts from which the metal oxide film is to be removed are taken off from the process chamber for washing. This extends the downtime of the processing apparatus that will follow the removal of the metal oxide film in the process chamber. As a result, the operation efficiency of the processing apparatus is decreased.

### [Processing Apparatus]

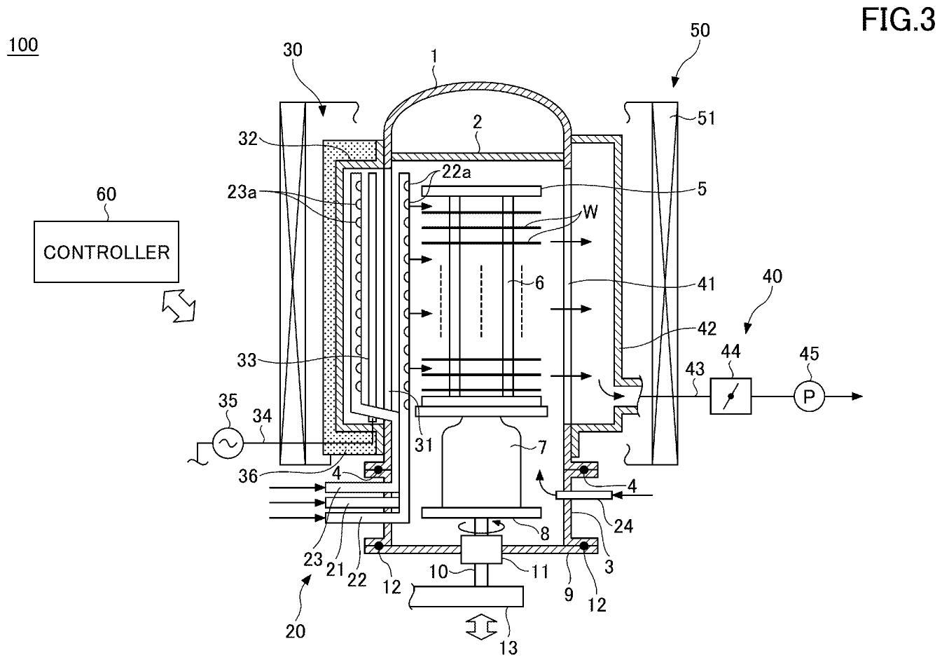

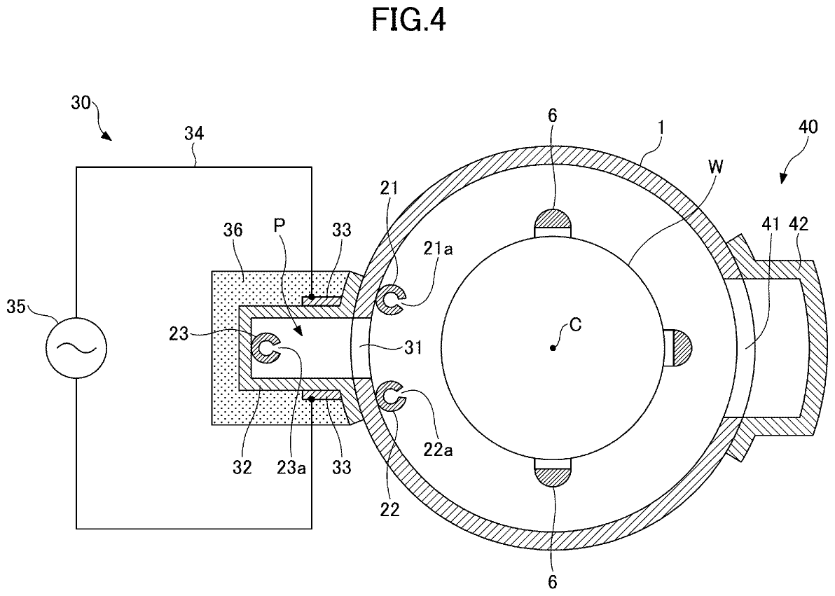

A processing apparatus 100 according to the embodiment will be described with reference to FIGS. 3 and 4. As illustrated in FIGS. 3 and 4, the processing apparatus 100 mainly includes a process chamber 1, a gas supply 20, a plasma generator 30, an exhauster 40, a heater 50, and a controller 60.

The process chamber 1 has a vertical cylindrical shape that includes the ceiling and is opened at the bottom thereof. The entirety of the process chamber 1 is formed of, for example, quartz. A ceiling plate 2 is provided near the top in the process chamber 1, and a region lower than the ceiling plate 2 is sealed. The ceiling plate 2 is formed of, for example, quartz. A manifold 3 formed of metal so as to have a cylindrical shape is connected via a seal member 4 to the opening at the bottom of the process chamber 1. The seal member 4 may be, for example, an O-ring.

The manifold 3 supports the bottom of the process chamber 1. A boat 5 is inserted into the process chamber 1 from below the manifold 3. The boat 5 approximately horizontally retains a plurality of (e.g., from 25 through 150) substrates W at intervals along an upward-and-downward direction. The substrate W may be, for example, a semiconductor wafer. The boat 5 is formed of, for example, quartz. The boat 5 includes, for example, three supports 6, and the plurality of substrates W are supported by grooves formed in each of the supports 6.

The boat 5 is placed on a rotatable stage 8 via a heat-retaining cylinder 7. The heat-retaining cylinder 7 is formed of, for example, quartz. The heat-retaining cylinder 7 suppresses release of heat from the opening at the bottom of the manifold 3. The rotatable stage 8 is supported on a rotation shaft 10. The opening at the bottom of the manifold 3 is opened and closed with a cover 9. The cover 9 is formed of, for example, a metal material such as stainless steel or the like. The rotation shaft 10 penetrates the cover 9.

A penetrating portion of the rotation shaft 10 is provided with a magnetic fluid seal 11. The magnetic fluid seal 11 airtightly seals the rotation shaft 10 and rotatably supports the rotation shaft 10. A seal member 12 is provided between a peripheral portion of the cover 9 and the bottom of the manifold 3 in order to maintain airtightness of the interior of the process chamber 1. The seal member 12 may be, for example, an O-ring.

The rotation shaft 10 is attached to a tip of an arm 13 supported by, for example, a raising and lowering mechanism such as a boat elevator or the like. In response to rising or lowering of the arm 13, the boat 5, the heat-retaining cylinder 7, the rotatable stage 8, and the cover 9 rise or lower integrally with the rotation shaft 10, and are inserted into or released from the process chamber 1.

The gas supply 20 supplies various gases into the process chamber 1. The gas supply 20 includes, for example, four gas nozzles 21 to 24. The gas supply 20 may, for example, include additional gas nozzles in addition to the four gas nozzles 21 to 24.

The gas nozzle 21 is formed of, for example, quartz. The gas nozzle 21 has an L shape that penetrates the lateral wall of the manifold 3 inward, and bends upward and extends vertically. A vertical portion of the gas nozzle 21 is provided outward of a plasma-generating space P, e.g., at a position that is closer to the plasma-generating space P than to a center C of the process chamber 1 in the process chamber 1. The vertical portion of the gas nozzle 21 may be provided, for example, at a position that is closer to a discharge port 41 than to the center C of the process chamber 1 in the process chamber 1. The gas nozzle 21 is connected to a source of one or more processing gases. The processing gases may include various gases used in precoat step S10, film formation step S20, and film removal step S40. For example, the processing gases include a silicon-containing gas and a metal-containing gas. In the vertical portion of the gas nozzle 21, a plurality of gas holes 21a are formed at intervals over a length thereof, in the upward-and-downward direction, corresponding to a substrate-supporting range of the boat 5. The gas holes 21a are, for example, oriented toward the center C of the process chamber 1 and discharge the processing gas in the horizontal direction toward the center C of the process chamber 1. The gas holes 21a may be, for example, oriented toward the plasma-generating space P or toward the inner wall near the process chamber 1.

The gas nozzle 22 is formed of, for example, quartz. The gas nozzle 22 has an L shape that penetrates the lateral wall of the manifold 3 inward, and bends upward and extends vertically. A vertical portion of the gas nozzle 22 is provided outward of the plasma-generating space P, e.g., at a position that is closer to the plasma-generating space P than to the center C of the process chamber 1 in the process chamber 1. The vertical portion of the gas nozzle 22 may be provided, for example, at a position that is closer to the discharge port 41 than to the center C of the process chamber 1 in the process chamber 1. The gas nozzle 22 is connected to a source of one or more processing gases. The processing gases may include various gases used in precoat step S10, film formation step S20, and film removal step S40. For example, the processing gases include a halogen-containing gas. In the vertical portion of the gas nozzle 22, a plurality of gas holes 22a are formed at intervals over a length thereof, in the upward-and-downward direction, corresponding to the substrate-supporting range of the boat 5. The gas holes 22a are, for example, oriented toward the center C of the process chamber 1 and discharge the processing gas in the horizontal direction toward the center C of the process chamber 1. The gas holes 22a may be, for example, oriented toward the plasma-generating space P or toward the inner wall near the process chamber 1.

The gas nozzle 23 is formed of, for example, quartz. The gas nozzle 23 has an L shape that penetrates the lateral wall of the manifold 3 inward, and bends upward and extends vertically. A vertical portion of the gas nozzle 23 is provided in the plasma-generating space P. The gas nozzle 23 is connected to a source of one or more processing gases. The processing gases may include various gases used in precoat step S10, film formation step S20, and film removal step S40. For example, the processing gases include an oxygen-containing gas. In the vertical portion of the gas nozzle 23, a plurality of gas holes 23a are formed at intervals over a length thereof, in the upward-and-downward direction, corresponding to the substrate-supporting range of the boat 5. The gas holes 23a are, for example, oriented toward the center C of the process chamber 1 and discharge the processing gas in the horizontal direction toward the center C of the process chamber 1.

The gas nozzle 24 is formed of, for example, quartz. The gas nozzle 24 has a straight-tube shape that penetrates the lateral wall of the manifold 3 and extends horizontally. A tip of the gas nozzle 24 is provided outward of the plasma-generating space P, e.g., in the process chamber 1. The gas nozzle 24 is connected to a source of a purge gas. The gas nozzle 24 has an opening at the tip thereof, and supplies the purge gas into the process chamber 1 from the opening. Examples of the purge gas include an inert gas, such as argon (Ar) gas, nitrogen (N₂) gas, and the like.

The plasma generator 30 is provided at a part of the lateral wall of the process chamber 1. The plasma generator 30 generates a plasma from the processing gas supplied from the gas nozzle 23. The plasma generator 30 includes a plasma partition wall 32, a pair of plasma electrodes 33, a power supply line 34, a radio frequency (RF) power source 35, and an insulating protective cover 36.

The plasma partition wall 32 is airtightly welded to the outer wall of the process chamber 1. The plasma partition wall 32 is formed of, for example, quartz. A cross section of the plasma partition wall 32 forms a recessed shape, and the plasma partition wall 32 covers an opening 31 formed in the lateral wall of the process chamber 1. The opening 31 is formed so as to be narrow and long in the upward-and-downward direction so as to cover all of the substrates W supported by the boat 5 in the upward-and-downward direction. The gas nozzle 23 is disposed in the plasma-generating space P that is defined by the plasma partition wall 32 and is an inner space in communication with the interior of the process chamber 1. The gas nozzle 21 and the gas nozzle 22 are provided at positions near the substrates W along the inner wall of the process chamber 1 external of the plasma-generating space P.

The pair of plasma electrodes 33 each have an elongated shape, and are disposed along the upward-and-downward direction so as to face the outer surfaces of the walls on both sides of the plasma partition wall 32. The power supply line 34 is connected to the bottom of each plasma electrode 33.

The power supply line 34 electrically connects each plasma electrode 33 and the RF power source 35 to each other. For example, one end of the power supply line 34 is connected to the bottom, which is a lateral portion of a shorter side of each plasma electrode 33, and the other end thereof is connected to the RF power source 35.

The RF power source 35 is electrically connected via the power supply line 34 to the bottom of each plasma electrode 33. The RF power source 35 supplies a RF power of, for example, 13.56 MHz to the pair of plasma electrodes 33. Thereby, the RF power is applied to the plasma-generating space P defined by the plasma partition wall 32.

The insulating protection cover 36 is attached to the outer surface of the plasma partition wall 32 so as to cover the plasma partition wall 32. An inner portion of the insulating protection cover 36 is provided with an unillustrated coolant-flowing path. By passing a coolant (e.g., cooled nitrogen gas) through the coolant-flowing path, the plasma electrodes 33 are cooled. Between the plasma electrodes 33 and the insulating protection cover 36, an unillustrated shield may be provided so as to cover the plasma electrodes 33. The shield is formed of, for example, a good conductor such as a metal or the like, and is electrically grounded.

The exhauster 40 is provided in an exhausting port 41 formed in a portion of the lateral wall of the process chamber 1, the portion facing the opening 31. The exhausting port 41 is formed so as to be narrow and long upward and downward correspondingly to the boat 5. A cover member 42 is attached to a portion of the process chamber 1 corresponding to the exhausting port 41. A cross section of the cover member 42 is formed in a U shape so as to cover the exhausting port 41. The cover member 42 extends upward along the lateral wall of the process chamber 1. An exhausting tube 43 is connected to a lower portion of the cover member 42. The exhausting tube 43 is provided with a pressure regulation valve 44 and a vacuum pump 45 in order from upstream to downstream in a gas-flowing direction. The exhauster 40 drives the pressure regulation valve 44 and the vacuum pump 45 based on control of the controller 60, and regulates the inner pressure of the process chamber 1 by the pressure regulation valve 44 while suctioning the gas in the process chamber 1 into the vacuum pump 45.

The heater 50 includes a heat generator 51. The heat generator 51 has a cylindrical shape that encloses the process chamber 1 outside in a radial direction of the process chamber 1. The heat generator 51 heats the entire lateral periphery of the process chamber 1, thereby heating the substrates W housed in the process chamber 1.

The controller 60, for example, controls the operations of the components of the processing apparatus 100. The controller 60 may be, for example, a computer. A program for causing the computer to execute the operations of the components of the processing apparatus 100 is stored in a storage medium. The storage medium may be, for example, a flexible disk, a compact disk, a hard disk, a flash memory, or a digital versatile disk (DVD).

### [Operations of the Processing Apparatus]

An operation in which the processing method according to the embodiment is performed in the processing apparatus 100 will be described. The following will be described taking, as an example, a case in which the precoat film is an a-Si film and the metal oxide film is an AlO film. The same may apply to cases in which the precoat film is a film other than the a-Si film and the metal oxide film is a film other than the AlO film.

First, the controller 60 controls the operations of the parts of the processing apparatus 100 so as to perform precoat step S10. Specifically, the controller 60 controls the raising and lowering mechanism to transfer the empty boat 5, which does not retain the substrate W, into the process chamber 1, and airtightly seal and close a lower-end opening of the process chamber 1 with a lid 9. Subsequently, for conditioning the process chamber 1, the controller 60 controls the exhauster 40 to reduce the pressure in the process chamber 1 to a predetermined pressure and controls the heater 50 to adjust the temperature in the process chamber 1 to a predetermined temperature. Subsequently, the controller 60 controls the gas supply 20 to supply a silicon-containing gas into the process chamber 1. Thereby, the interior of the process chamber is coated with an a-Si film. Subsequently, the controller 60 raises the pressure of the interior of the process chamber 1 to atmospheric pressure and cools the interior of the process chamber 1 to a temperature suitable for discharge of the boat 5. Subsequently, the controller 60 controls the raising and lowering mechanism to discharge the boat 5 from the interior of the process chamber 1.

Next, the controller 60 controls the operations of the parts of the processing apparatus 100 so as to perform the film formation step S20. Specifically, the controller 60 controls the raising and lowering mechanism to transfer the boat 5 retaining the substrates W into the process chamber 1, and airtightly seal and close the lower-end opening of the process chamber 1 with the lid 9. Subsequently, for conditioning the process chamber 1, the controller 60 controls the exhauster 40 to reduce the pressure in the process chamber 1 to a predetermined pressure and controls the heater 50 to adjust the temperature in the process chamber 1 to a predetermined temperature. Subsequently, the controller 60 controls the gas supply 20 to supply an Al-containing gas and an oxygen-containing gas into the process chamber 1. Thereby, an AlO film is formed on each of the substrates W. At this time, the controller 60 may control the plasma generator 30 to supply an RF power from the RF power source 35 to the pair of plasma electrodes 33, thereby generating a plasma from the oxygen-containing gas supplied into the process chamber 1. Subsequently, the controller 60 raises the pressure of the interior of the process chamber 1 to the atmospheric pressure and cools the interior of the process chamber 1 to a temperature suitable for discharge of the boat 5. Subsequently, the controller 60 controls the raising and lowering mechanism to discharge the boat 5 from the interior of the process chamber 1.

Next, the controller 60 controls the operations of the parts of the processing apparatus 100 so as to repeatedly perform film formation step S20 until film formation step S20 has been performed a set number of times (determination step S30).

After film formation step S20 has been performed the set number of times, the controller 60 controls the operations of the parts of the processing apparatus 100 so as to perform film removal step S40. Specifically, the controller 60 controls the raising and lowering mechanism to transfer the empty boat 5, which does not retain the substrate W, into the process chamber 1, and airtightly seal and close the lower-end opening of the process chamber 1 with the lid 9. Subsequently, for conditioning the process chamber 1, the controller 60 controls the exhauster 40 to reduce the pressure in the process chamber 1 to a predetermined pressure and controls the heater 50 to adjust the temperature in the process chamber 1 to a predetermined temperature. Subsequently, the controller 60 controls the gas supply 20 to supply a halogen-containing gas into the process chamber 1. At this time, the controller 60 controls the exhauster 40 to adjust the pressure in the process chamber 1, thereby forming an environment in which wet (liquid phase)-like reaction using the halogen-containing gas occurs in the interior of the process chamber. Thus, it is possible to remove the AlO film deposited, on the inner wall of the process chamber 1, the boat 5, and the like, by repeatedly performing film formation step S20. Note that, removal of the AlO film is not performed through complete wet etching reaction, and thus, AlF can be formed. Especially, if it takes an extended time to continuously supply the halogen-containing gas, halogenation of the AlO film proceeds from the surface thereof to a deeper position, and etching of the AlO film cannot sufficiently proceed. Therefore, every time the halogen-containing gas is supplied into the process chamber 1 for a predetermined time, the controller 60 stops the supply of the halogen-containing gas into the process chamber 1. Subsequently, the controller 60 controls the gas supply 20 to supply the oxygen-containing gas into the process chamber 1 and controls the plasma generator 30 to supply the RF power from the RF power supply 35 to the pair of plasma electrodes 33, thereby generating a plasma from the oxygen-containing gas supplied into the process chamber 1. By the action of the oxygen radicals, AlF is discharged from the interior of the process chamber in the form of gas of, for example, AlO or a halogen (e.g., F). In this way, every time the halogen-containing gas is supplied into the process chamber 1 for a predetermined time, the controller 60 stops the supply of the halogen-containing gas into the process chamber 1 and controls the gas supply 20 so as to supply oxygen radicals into the process chamber 1. In this case, the metal oxide film can be continuously etched, involving approximately no reduction in the etching rate. Subsequently, the controller 60 raises the pressure of the interior of the process chamber 1 to the atmospheric pressure and cools the interior of the process chamber 1 to a temperature suitable for discharge of the boat 5. Subsequently, the controller 60 controls the raising and lowering mechanism to discharge the boat 5 from the interior of the process chamber 1.

### Examples

Examples will be described below. In the examples, it is confirmed that an AlO film, which is a metal oxide film, can be removed by the processing method according to the embodiment.

In the examples, a silicon wafer including an AlO film on the surface thereof was provided. The provided silicon wafer was housed in the above-described processing apparatus 100, and film removal step S40 according to the embodiment was performed. In the examples, film removal step S40 was performed under a plurality of sets of conditions in which the pressure in the process chamber 1 was different, and the etching amount of the AlO film formed on the surface of the silicon wafer was measured. The conditions of film removal step S40 were as follows.

### (Halogen-Containing Gas Supply Step S41)

Temperature: room temperature
Pressure: 40 Torr, 50 Torr, 60 Torr, 70 Torr, or 100 Torr
Halogen-containing gas: hydrogen fluoride gas+nitrogen gas
Time: 10 minutes (oxygen radical supply step S42)
Temperature: room temperature
Pressure: 0.3 Torr
Oxygen-containing gas: oxygen gas
RF power: 100 W
Time: 10 minutes (determination step S43)
Set number of times: 10 times

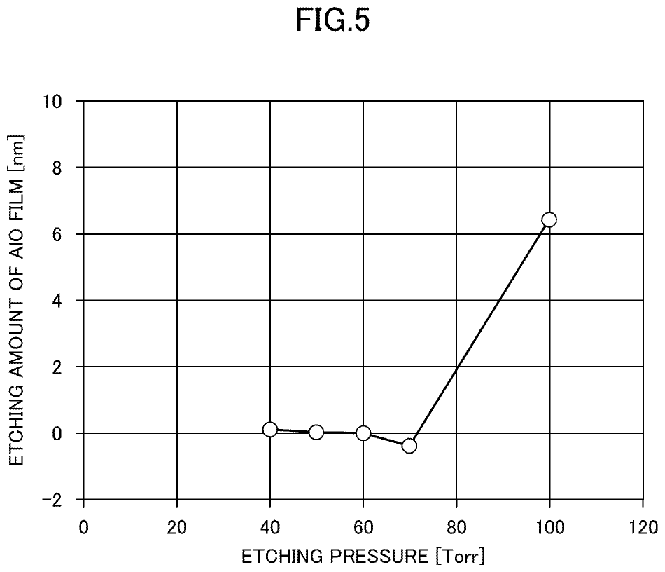

FIG. 5 is a graph illustrating a relationship between the etching pressure and the etching amount of the AlO film. In FIG. 5, the horizontal axis indicates an etching pressure [Torr], which is the pressure in the process chamber 1 in halogen-containing gas supply step S41, and the vertical axis indicates an etching amount [nm] of the AlO film.

As indicted in FIG. 5, when the etching pressure was from 40 Torr through 70 Torr, the AlO film was not etched, but when the etching pressure was 100 Torr, the AlO film was etched. From this result, it was indicated that the AlO film could be etched by increasing the pressure in the process chamber 1 to 100 Torr or higher in halogen-containing gas supply step S41.

According to the present disclosure, a metal oxide film can be removed through a dry process.

It should be understood that the embodiments disclosed herein are illustrative and not restrictive in all respects. Various omissions, substitutions, and changes may be made to the above-described embodiments without departing from the scope of claims recited and the spirit of the disclosure.

The above-described embodiments are related to the batch-type processing apparatus configured to perform the process to the plurality of substrates all at once, but the present disclosure is not limited thereto. For example, the processing apparatus may be a single wafer processing apparatus configured to process a plurality of substrates one by one. For example, the processing apparatus may be a semi-batch-type apparatus configured to rotate a plurality of substrates disposed on a rotation table in a process chamber by rotating the rotation table, and allow the substrates to sequentially pass through a region where a first gas is supplied and a region where a second gas is supplied, thereby performing treatments to the substrates.

It should be understood that the embodiments disclosed herein are illustrative and not restrictive in all respects. Various omissions, substitutions, and changes may be made to the above-described embodiments without departing from the scope of claims recited and the spirit of the disclosure.

What is claimed is:

1. A processing method, comprising:
a) supplying a halogen-containing gas into a process chamber and removing a metal oxide film in the process chamber.

2. The processing method according to claim 1, wherein
a) includes maintaining an interior of the process chamber at a temperature of from room temperature through 40° C.

3. The processing method according to claim 2, wherein
the halogen-containing gas is hydrogen fluoride gas,
the metal oxide film is an aluminum oxide film, and
a) includes maintaining the interior of the process chamber at 13.3 kPa or higher.

4. The processing method according to claim 1, further comprising:
b) supplying oxygen radicals into the process chamber and removing a metal halide formed in a); and
c) alternatingly performing a) and b).

5. The processing method according to claim 2, further comprising:
b) supplying oxygen radicals into the process chamber and removing a metal halide formed in a); and
c) alternatingly performing a) and b).

6. The processing method according to claim 3, further comprising:
b) supplying oxygen radicals into the process chamber and removing a metal halide formed in a); and
c) alternatingly performing a) and b).

7. The processing method according to claim 4, further comprising:
d) coating an interior of the process chamber with a film having etching resistance to the halogen-containing gas higher than in a material that forms the process chamber; and
e) performing, one or more times, a process of housing a substrate in the process chamber and forming the metal oxide film on the substrate, wherein
e) is performed after d), and
c) is performed after e).

8. The processing method according to claim 5, further comprising:
d) coating an interior of the process chamber with a film having etching resistance to the halogen-containing gas higher than in a material that forms the process chamber; and
e) performing, one or more times, a process of housing a substrate in the process chamber and forming the metal oxide film on the substrate, wherein
e) is performed after d), and
c) is performed after e).

9. The processing method according to claim 6, further comprising:
d) coating an interior of the process chamber with a film having etching resistance to the halogen-containing gas higher than in a material that forms the process chamber; and
e) performing, one or more times, a process of housing a substrate in the process chamber and forming the metal oxide film on the substrate, wherein
e) is performed after d), and
c) is performed after e).

10. A processing apparatus, comprising:
a process chamber;
a gas supply configured to supply a halogen-containing gas into the process chamber; and
a controller, the controller including
a processor, and
a memory storing one or more programs, which when executed, cause the processor to:
control the gas supply to perform a process of supplying the halogen-containing gas into the process chamber and removing a metal oxide film in the process chamber.
